(19) United States
(12) Patent Application Publication
(10) Pub. No.: US 2017/0076875 A1
(43) Pub. Date: Mar. 16, 2017

(54) CdZnO/Si Tandem Cell for Photoelectrochemical Water Dissociation

(71) Applicants: Wladyslaw Walukiewicz, Kensington, CA (US); Douglas Detert, Berkeley, CA (US); Kin Man Yu, LaFayette, CA (US); Mimoza Ristova, Skopje (MK)

(72) Inventors: Wladyslaw Walukiewicz, Kensington, CA (US); Douglas Detert, Berkeley, CA (US); Kin Man Yu, LaFayette, CA (US); Mimoza Ristova, Skopje (MK)

(21) Appl. No.: 14/851,630

(22) Filed: Sep. 11, 2015

(51) Int. Cl. H01G 9/20; C25B 1/00; C25B 1/04; H01L 31/0687; H01L 31/028

(52) U.S. Cl. CPC H01G 9/2081; H01L 31/0687; H01L 31/028; H01G 9/204; C25B 1/04; C25B 1/003

(57) ABSTRACT

Here we present an apparatus comprising a photoelectrochemical cell connected a photovoltaic device, comprised of a layer with a thick n-type absorber and a layer comprising a thin p-type hole emitter. The photoelectrochemical cell has binary, metal-oxide semiconductors with wide bandgaps comprising high electron affinities relative to other semiconductor materials allowing for n-type doping.

### RELATED APPLICATIONS

This application claims the benefit of U.S. Provisional Application 62/049,003 filed on Sep. 11, 2014 which is herein incorporated in its entirety.

### STATEMENT OF GOVERNMENT SUPPORT

This invention was made with government support under Contract No. DE-AC02-05CH11231 awarded by the U.S. Department of Energy. The government has certain rights in this invention.

### TECHNICAL FIELD

This disclosure relates generally to devices for water dissociation and more particularly to a photoelectrochemically active layer tandem cell for photoelectrochemical water dissociation.

### BACKGROUND

Semiconductor materials for the spontaneous photoelectrochemical dissociation of water have to satisfy several conditions: i) the material needs to have a direct energy gap of about 1.9 eV; ii) the conduction band edge needs to be located above the water/hydrogen reduction potential H⁺/H₂ (at about 4.5 eV below the vacuum level) and the valence band edge needs to be located below the water oxidation potential O₂/H₂O (5.7 eV below the vacuum level); iii) the electrostatics of semiconductor/water interface should facilitate rapid reactions between photoexcited electrons (holes) and positive (negative) ions in the water; and vi) the material needs to exhibit long-term resistance of the semiconductor surface to the corrosive effects of the photoelectrochemical reactions.

Currently, there is no known semiconductor material that satisfies all these conditions. More complex schemes for photoelectrochemical cells are based on tandem approaches using either tandem solar cells that provide an internal, light-induced bias to drive the water splitting reactions, or so-called “Z” schemes that use two or more semiconductor materials with different gaps. To date, however, none of the schemes has been demonstrated to operate as a durable device for spontaneous solar water dissociation.

Work done in this area can be seen in Journal of Applied Physics 115, 233708 (2014) and Applied Physics Letters 102, 232103 (2013) which are both incorporated in full herein by reference.

### SUMMARY

Details of one or more embodiments of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows valence band maximum (VBM) and conduction band minimum (CBM) positions as a function of Cd content for CdₓZn₁₋ₓO as determined by irradiation/Fermi-level-pinning experiments.

FIG. 2 shows a proposed CdZnO/Si heterojunction device for PEC water splitting applications.

FIG. 3 shows photon transmittance and accumulative photon count of commercial FTO and CdO:In films. Significant improvement in transmission of NIR photons (>λ=1130 nm) with CdO:In. More gain for longer wavelength absorbers.

FIG. 4 represents a current-voltage curve of CdO:In/p-Si where resistance of optimized p-Si/CdO:In interface does not contribute to the total series resistance.

FIG. 5 shows conductivity as a function of Cd content in the as-grown, colored, and bleached NixCd1-xO films. Alloying of CdO with NiO reduces the decomposition. CdNiO with more than 25% Ni can be used as a protective coating.

### DETAILED DESCRIPTION

Reference will now be made in detail to some specific examples of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims.

In the following description, numerous specific details are set forth in order to provide a thorough understanding of the present invention. Particular example embodiments of the present invention may be implemented without some or all of these specific details. In other instances, well known process operations have not been described in detail in order not to unnecessarily obscure the present invention.

Various techniques and mechanisms of the present invention will sometimes be described in singular form for clarity. However, it should be noted that some embodiments include multiple iterations of a technique or multiple instantiations of a mechanism unless noted otherwise.

### Introduction

CdO and ZnO are both binary, metal-oxide semiconductors with wide bandgaps. The electron affinities of CdO and ZnO are extremely high relative to other semiconductor materials, resulting in their extreme propensity for n-type doping. For this reason, both compounds are used in transparent conducting oxide (TCO) applications, such as transparent contacts for photovoltaics. ZnO has a direct bandgap of 3.3 eV and is notable for its strong luminescence properties, while CdO has both an indirect (˜1.1 eV) and direct (2.3 eV) bandgap, giving rise to potentially long charge carrier lifetimes in the material. The properties of each of these binary compounds are well known, but previous investigations offered little reliable information about the properties and electronic structure of CdO—ZnO alloys.

The studies presented herein focus on the synthesis and characterization of CdₓZn₁₋ₓO films, with the goal of correlating their structural, optical, and electrical properties, and to explore changes in the electronic structure as a function of composition. Of particular interest are the absolute energy levels of the valence band maximum (VBM) and conduction band minimum (CBM), as these determine how the material will behave electrically and optically when integrated into devices such as photoelectrochemical (PEC) devices for water splitting.

A pulsed, filtered cathodic arc deposition (PFCAD) was used to deposit thin films of CdₓZn₁₋ₓ onto glass substrates. The films were characterized by standard structural (X-ray diffraction), optical (absorption and photoluminescence), and electrical (Hall effect) techniques. To assess how the composition-dependence of the direct optical gaps is related to energy shifts of the conduction and valence bands, the bulk Fermi level of each alloy at the Fermi stabilization energy (EFS) were pinned, located ˜4.9 eV below the vacuum level, using particle irradiation (120 keV Ne+). Due to the high electron affinities of ZnO and CdO (˜4.9 eV and 5.9 eV, respectively), the Fermi level of the irradiated samples falls within the conduction band. The electron affinity can be then calculated from the final saturation concentration of electrons.

One result of these studies was the determination of the alloy composition dependent location of the valence band maxima the conduction band minima relative to the vacuum level and water redox potentials.

### Results

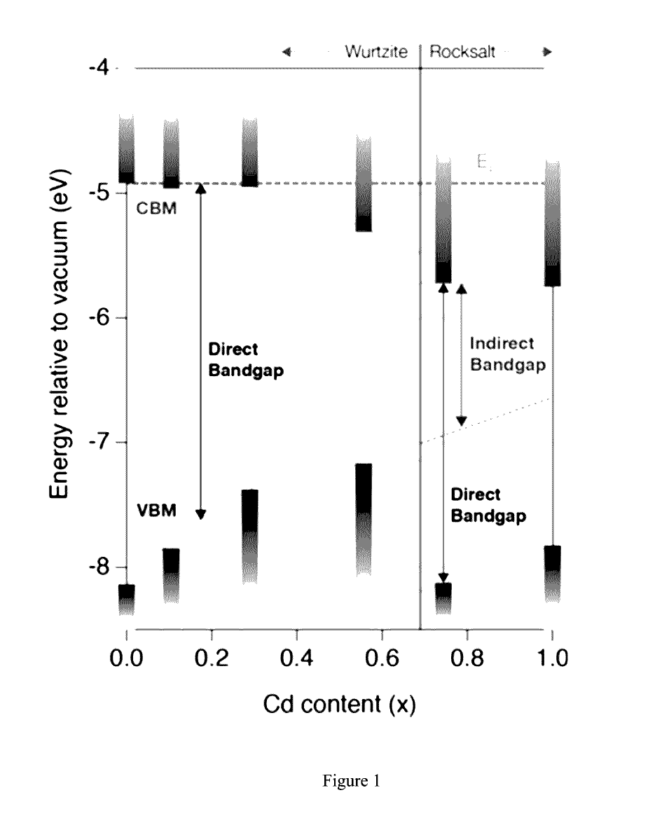

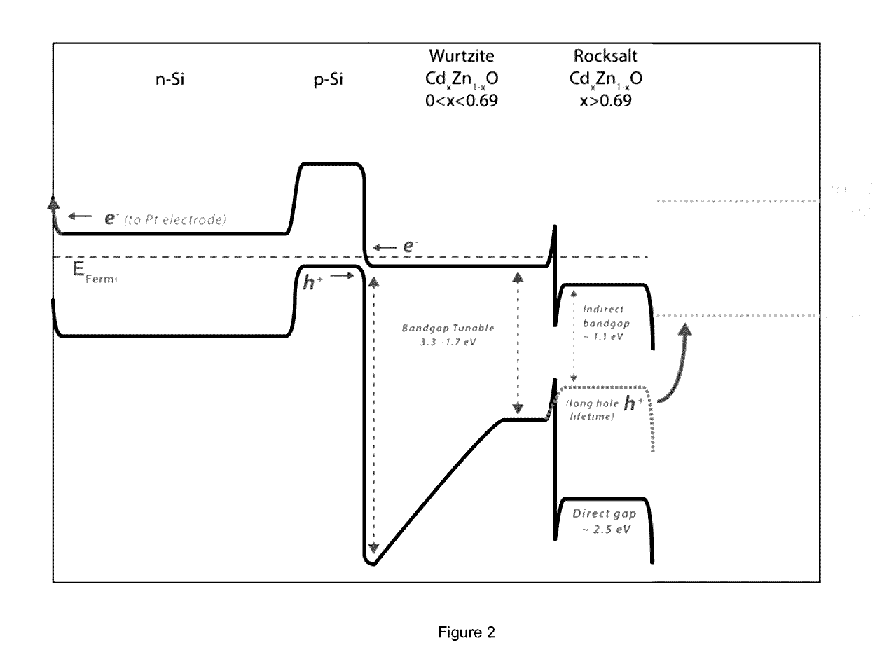

The results show that the structurally mismatched endpoints of this alloy system (ZnO takes on the hexagonal wurtzite (WZ) structure while CdO is cubic rocksalt (RS)) results in two distinct regions of optical and electrical behavior. As seen in FIG. 1, the direct bandgap of wurtzite CdₓZn₁₋ₓO can be tuned from 3.3 eV (ZnO) to 1.7 eV (x=0.69), as a result of a significant rise in the VBM toward the vacuum level. At the transition composition the conduction band shifts abruptly downward and the new valence band maximum appears in the L symmetry direction. As a result, the alloys become indirect gap semiconductors for x>0.69. This unusual change in the electronic band structure offers a potential for using the CdZnO alloy system for a tandem photoelectrochemical cell that satisfies all the material conditions for solar water splitting. The proposed cell structure that is schematically shown in FIG. 2 comprises a nip Si junction followed CdZnO layer compositionally graded from ZnO, (or high Zn-content CdZnO) to CdO (or high Cd-content CdZnO alloy).

Based on this unusual electronic band structure and the conduction and valence band edge positions, a novel photoelectrochemical cell (PEC) for spontaneous, solar light-induced water dissociation is proposed. The proposed structure, shown in FIG. 2, is a heterojunction PEC device that relies on a photoelectrochemically active layer (in this case, multiple layers of CdZnO) connected in series with a photovoltaic device (Si). This overall device architecture is referred to as the “D4” concept, as it requires four photons to split each molecule of water.

The base of the device is a standard Si n-p solar cell comprising a thick n-type absorber and a thin p-type hole emitter layer. Photogenerated electrons in these layers move to the cathode (not pictured) to carry out the hydrogen reduction part of the water splitting reaction. The photoanode, grown directly on the Si underlayer to form an ohmic contact, consists of direct gap WZ-CdZnO with a graded composition from pure ZnO (or large Zn-content CdZnO) to x=0.69 (direct E_{g}=1.7 eV) and a top layer of indirect-gap RS-CdZnO or CdO. Photogenerated electrons in the WZ layer recombine with photogenerated holes from the Si base layers, while holes generated in the WZ layer are swept in the opposite direction, toward the anode surface, as a result of the internal electric field that is generated by the upward rise in the valence band minimum (VBM) with increasing Cd composition.

The holes transferred to the indirect valence band maximum in the RS-CdZnO top layer are predicted to have long lifetimes (on the order of microseconds). The long-lived holes move to the surface in contact with water and complete the water dissociation reaction through the oxidation of water molecules. The proposed device structure has an advantage of combining a direct-gap semiconductor layer that strongly absorbs solar photons with an indirect-gap semiconductor layer that exhibits long hole lifetimes. In addition, the direct gap WZ structure absorber with the bandgap of 1.7 eV splits the solar spectrum with Si into two current-matching portions. The charge at the semiconductor/water interface can be controlled by intentional doping of the top CdO layer. The CdO semiconductor surface has an electron accumulation layer with positively charged surface donors that gives rise to an electron concentration of 4×10²⁰ cm⁻³ and a surface depletion layer with negatively charged surface acceptors for higher electron concentrations. The flat band condition is realized for n=4×10²⁰ cm⁻³.

At low to moderate Cd content (x<0.69), the alloy system films are predominantly WZ-structured and exhibit a direct energy gap and strong band edge photoluminescence that can be tuned from 3.3 eV (pure ZnO) to 1.7 eV. At high Cd content (x>0.69), the films are RS-structured, have a high electron mobility (˜90 cm² V⁻¹s⁻¹), and exhibit an indirect bandgap (no detectable luminescence) and a larger direct gap that can be tuned from 2.3 eV (pure CdO) to 2.6 eV (x=0.75).

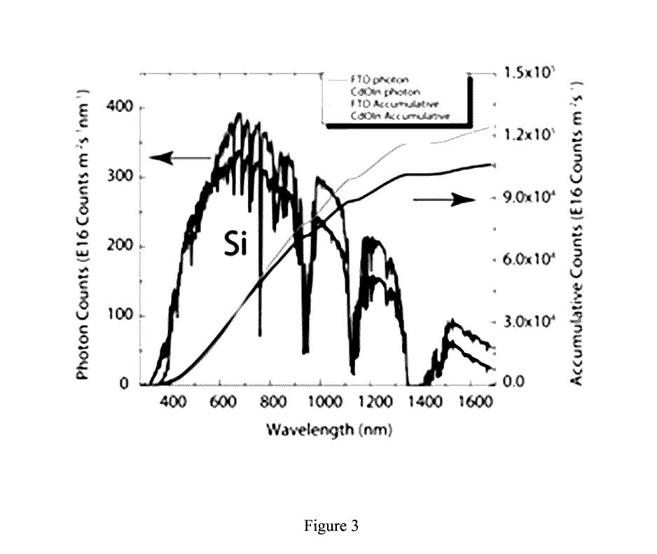

FIG. 3 shows the photon transmittance and accumulative photon count for solar spectrum passing through CdO:In and commercially available FTO of the same sheet resistance. A significant improvement in the transmission of NIR photons in CdO:In fully compensates for the small deficiency in UV transparency of this TCO. An accumulative photon count shows an advantage of the CdO based TCO for absorbers with λg>800 nm (Eg<1.6 eV). The superior NIR transparency demonstrates the feasibility of using CdO TCO in Si PV technology with 4=1130 nm.

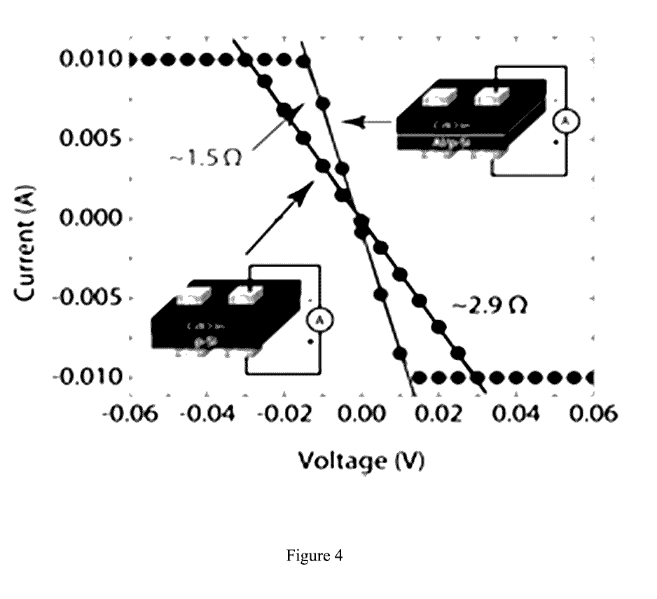

Applications of CdO TCO to Si PV technology require low resistance ohmic contacts between CdO TCO and Si. To satisfy this low resistance, CdO:In films were placed on p-type Si with very low contact resistance. FIG. 4 shows the current-voltage curve of CdO:In/p-Si heterostructure. The resistance of optimized p-Si/CdO:In interface does not contribute to the total series resistance of a standard Si solar cell. The contact resistance is further reduced by Al diffusion from Al interlayer at the interface.

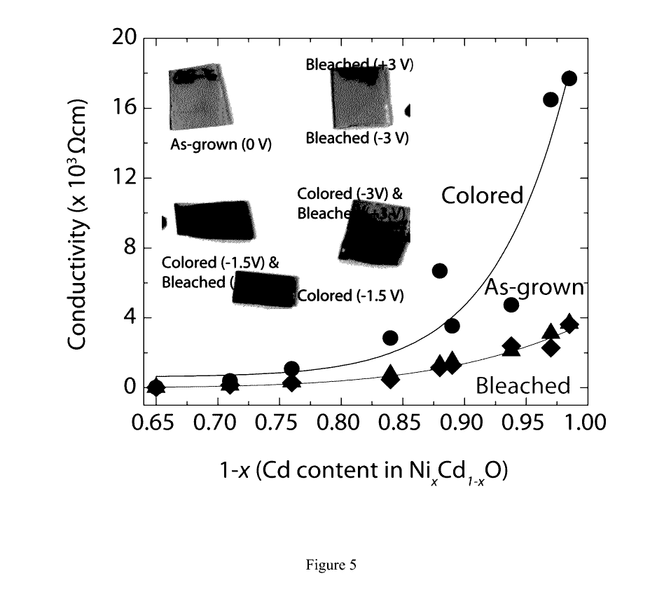

An environmental stability is an important consideration for applications of CdO TCO. The decomposition of CdO-based TCOs under highly corrosive conditions is significantly reduced by alloying CdO with NiO. FIG. 5 displays the conductivity as a function of Cd content in the NixCd1-xO films. The films exposed to a negative bias in an electrolyte become more conductive and less transparent (colored) due to loss of oxygen and material decomposition. The alloying of CdO with NiO reduces the decomposition. Coloration effect is decreasing with increasing Ni content and becomes negligible for Ni content larger than ˜25%. The coloration effect has been attributed to the presence of the surface electron accumulation layer as the films show much larger stability for the positive bias (bleaching) conditions.

### CONCLUSION

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

We claim:

1. An apparatus comprising:
a. a photoelectrochemical cell connected in series with a photovoltaic device, wherein:
i. said photovoltaic device comprising a layer comprising a thick n-type absorber and a layer comprising a thin p-type hole emitter; and
ii. said photoelectrochemical cell comprising binary, metal-oxide semiconductors with wide bandgaps comprising high electron affinities relative to other semiconductor materials allowing n-type doping.

2. The apparatus of claim 1 further wherein said photovoltaic device comprises an Si solar cell wherein said Si solar cell comprises an nip Si junction.

3. The apparatus of claim 2 further comprising said nip Si junction wherein said p-Si is adjacent to a CdZnO layer, wherein said CdZnO layer is compositionally graded from a high Zn content alloy to a high Cd content alloy.

4. The apparatus of claim 2 further comprising said nip Si junction wherein said p-Si is adjacent to a CdZnO layer, wherein said CdZnO layer is compositionally graded from CdZnO Wurtzite, to CdZnO Rock Salt.

5. The apparatus of claim 3 further comprising a low resistance ohmic contact between cadmium oxide and p-Si.

6. The apparatus of claim 4 wherein said photoelectrochemically active layer comprises CdₓZn₁₋ₓ; wherein:
a. said Wurtzite comprises a Cd content greater than zero but less than about 0.69; and
b. said Rock Salt comprises a Cd content greater than about 0.69.

7. The apparatus of claim 1 further comprising a heterojunction photoelectrochemical cell comprising at least one photoelectrochemically active layer connected in series with a photovoltaic device.

8. The apparatus of claim 5 further comprising a photoanode, wherein:
a. said photoanode is grown directly on said Si underlayer, forming an ohmic contact;
b. said photoanode comprises
i. direct gap WZ-CdZnO with a graded composition from large Zn-content CdZnO to x=0.69 (direct E_{g}=1.7 eV); and
ii. indirect-gap RS-CdZnO with a graded composition from large Cd-content CdZnO.

9. The apparatus of claim 1 wherein said photochemical cell comprising at least one layer of alloy comprising CdO and NiO.

10. The apparatus of claim 9 wherein said alloy further comprises Ni content of at least 1 to 30 percent of alloy.

11. An apparatus comprising:
a. a Si solar cell comprising a thick n-type absorber and a thin p-type hole emitter layer; a cathode; and a photoanode; wherein
b. photogenerated electrons in the solar cell move to the cathode to carry out reduction reactions;

12. The apparatus of claim 9, wherein:
a. said photoanode comprises direct gap Wurtzite CdZnO with a graded composition from pure ZnO (or large Zn-content CdZnO) to x=0.69 (direct E_{g}=1.7 eV) and a top layer of indirect-gap RS-CdZnO or CdO;
b. photogenerated electrons in the WZ layer recombine with photogenerated holes from the Si base layers, while holes generated in the WZ layer are swept in the opposite direction, toward the anode surface, as a result of the internal electric field that is generated by the upward rise in the VBM with increasing Cd composition.
